(19) United States
(12) Patent Application Publication
(10) Pub. No.: US 2018/0270952 A1
(43) Pub. Date: Sep. 20, 2018

(54) MODULE, ELECTRONIC APPARATUS, AND WIRING BOARD

(71) Applicant: KABUSHIKI KAISHA TOSHIBA, Tokyo (JP)

(72) Inventors: Hiroshi OTA, Misato Saitama (JP); Daigo SUZUKI, Kawasaki Kanagawa (JP); Yasutomo SAKURAI, Kawasaki Kanagawa (JP); Hitoshi SAITOU, Yokohama Kanagawa (JP)

(21) Appl. No.: 15/694,962

(22) Filed: Sep. 4, 2017

(30) Foreign Application Priority Data
Mar. 15, 2017 (JP) 2017-050370

(51) Int. Cl. H05K 1/11

(52) U.S. Cl. CPC H05K 1/115; H05K 3/0047; H05K 2201/098; H05K 2201/10303

(57) ABSTRACT

A module includes a substrate, a first wiring, a second wiring, and an interlayer connection section. The substrate includes a first surface facing a first direction, a second surface facing a second direction opposite to the first direction, and an inner surface of a hole extending between the first surface and the second surface. The first wiring is provided on the first surface. The second wiring is provided on the second surface. The interlayer connection section includes a first conductor provided on the inner edge, connected to the first wiring and the second wiring, thinner than the first wiring, and thinner than the second wiring, and a second conductor disposed in the hole and electrically connected to the first conductor.

This application is based upon and claims the benefit of priority from Japanese Patent Application No. 2017-050370, filed Mar. 15, 2017, the entire contents of which are incorporated herein by reference.

### FIELD

Embodiments described herein relate generally to a module, an electronic apparatus, and a wiring board.

### BACKGROUND

In an electronic apparatus, a wiring provided on one surface of a substrate is connected to a wiring provided on another surface of the substrate by vias. Known via types include a through-hole obtained by forming a conductor, for example, plating or sputtering, on an inner surface of a hole provided in the substrate.

### DESCRIPTION OF THE DRAWINGS

FIG. 1 is a plan view schematically illustrating an electronic apparatus according to a first embodiment.

FIG. 2 is a cross-sectional view schematically illustrating a module according to the first embodiment along a line F2-F2 of FIG. 1.

FIG. 3 is a perspective view schematically illustrating a part of a first wiring, a part of a second wiring, and a via according to the first embodiment.

FIG. 4 is a plan view schematically illustrating a part of a wiring board according to the first embodiment.

FIG. 5 is a plan view schematically illustrating a part of a second surface of the wiring board according to the first embodiment.

FIG. 6 is a plan view schematically illustrating a part of the wiring board according to a second embodiment.

FIG. 7 is a perspective view schematically illustrating a part of the first wiring, a part of the second wiring, and the via according to a third embodiment.

FIG. 8 is a perspective view schematically illustrating a part of the first wiring, a part of the second wiring, and the via according to a fourth embodiment.

FIG. 9 is a perspective view schematically illustrating a part of the first wiring, a part of the second wiring, and the via according to a fifth embodiment.

FIG. 10 is a cross-sectional view schematically illustrating the module according to a sixth embodiment.

### DETAILED DESCRIPTION

A thickness of a conductor formed on an inner surface of a hole may be less than a thickness of a wiring. In this case, a magnitude of a current that can flow through one via is less than that of a current that can flow through the wiring.

In general, according to one embodiment, a module includes a substrate; a first wiring; a second wiring; and an interlayer connection section. The substrate includes a first surface facing a first direction, a second surface facing a second direction opposite to the first direction, and an inner surface of a hole extending between the first surface and the second surface. The first wiring is provided on the first surface. The second wiring is provided on the second surface. The interlayer connection section includes a first conductor provided on the inner edge, connected to the first wiring and the second wiring, thinner than the first wiring, and thinner than the second wiring, and a second conductor disposed in the hole and electrically connected to the first conductor.

### First Embodiment

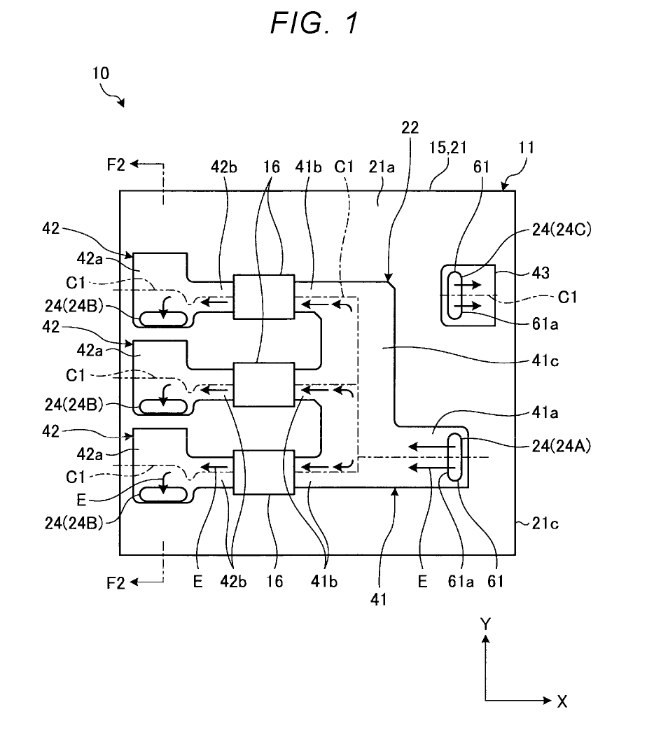

A first embodiment will be described hereinafter with reference to FIGS. 1 to 5. It is noted that a plurality of expressions are often used for constituent elements according to embodiments and description of the constituent elements in the present specification. The constituent elements and the description thereof expressed in a plurality of ways may be expressed in other ways not described herein. Furthermore, the constituent elements and the description not expressed in a plurality of ways may be expressed in other ways not described herein.

FIG. 1 is a plan view schematically illustrating an electronic apparatus 10 according to the first embodiment. The electronic apparatus 10 according to the present embodiment includes, for example, a three-phase brushless motor and drives the three-phase brushless motor by supplying a current thereto. It is noted that the electronic apparatus 10 is not limited to this example but may be another apparatus.

As shown in FIG. 1, the electronic apparatus 10 includes a module 11. The module 11 is connected to the three-phase brushless motor. The module 11 includes a wiring board 15 and three electronic components 16. The wiring board 15 is a so-called thick copper board through which a relatively high current is fed. It is noted that the wiring board 15 is not limited to this example but may be another wiring board.

The electronic components 16 are, for example, switching elements such as a field effect transistors (FETs). It is noted that the electronic components 16 are not limited to this example but may be other electronic components such as insulated gate bipolar transistors (IGBTs) or capacitors. The electronic components 16 are mounted on the wiring board 15.

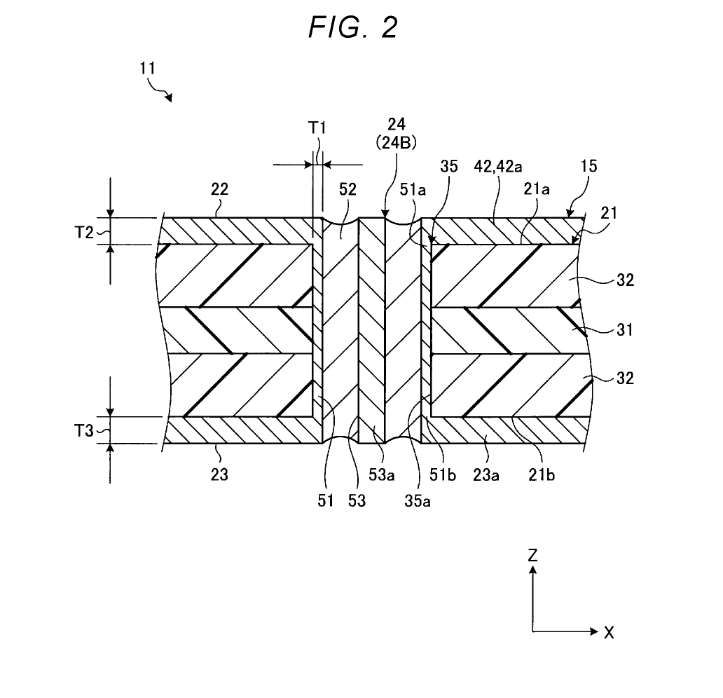

FIG. 2 is a cross-sectional view schematically illustrating the module 11 according to the first embodiment along a line F2-F2 of FIG. 1. As shown in FIG. 2, the module 11 includes a substrate 21, a first wiring 22, a second wiring 23, and a plurality of vias 24. The vias 24 are an example of interlayer connection sections and can be also referred to as, for example, conductive sections.

As shown in FIG. 1, the substrate 21 is formed into a generally quadrangular plate shape. It is noted that the substrate 21 may be formed into another shape. As shown in each drawing, an X-axis, a Y-axis, and a Z-axis are defined as follows in the present specification. The X-axis, the Y-axis, and the Z-axis are orthogonal to one another. The X-axis is along a length of the substrate 21. The Y-axis is along a width of the substrate 21. The Z-axis is along a thickness of the substrate 21.

As shown in FIG. 2, the substrate 21 includes, for example, a core material 31 and a plurality of prepregs 32. The core material 31 and the prepregs 32 exhibit, for example, insulation properties and are stacked in a direction along the Z-axis.

The substrate 21 includes a first surface 21a and a second surface 21b. The first surface 21a and the second surface 21b are front surfaces of the substrate 21. It is noted that the first surface 21a and the second surface 21b are not limited to this example. For example, when the wiring board 15 is a multilayer printed circuit board, the first surface 21a and the second surface 21b may be front surfaces of one of the prepregs 32 on which conductor patterns are provided, which are bonded to the other prepreg 32, and which are located within the substrate 21. The first surface 21a and the second surface 21b can be also referred to as, for example, “layers”.

The first surface 21a is a generally flat surface that spreads on an X-Y plane and faces in a normal direction along the Z-axis (direction indicated by an arrow of the Z-axis). The normal direction along the Z-axis is an example of a first direction. The second surface 21b is a generally flat surface that spreads on the X-Y plane and faces in a negative direction along the Z-axis (direction opposite to the arrow of the Z-axis). The negative direction along the Z-axis is the opposite direction to the normal direction along the Z-axis and is an example of a second direction. The second surface 21b is located opposite to the first surface 21a.

A plurality of holes 35 are provided in the substrate 21. The holes 35 each penetrate the substrate 21 in the direction along the Z-axis and have openings in the first surface 21a and the second surface 21b, respectively. In other words, the holes 35 extend in the direction along the Z-axis. The direction along the Z-axis includes the normal direction along the Z-axis and the negative direction along the Z-axis, is orthogonal to (crosses) the first surface 21a, and is orthogonal to (crosses) the second surface 21b. The direction along the Z-axis is an example of a 14th direction. It is noted that the holes 35 are not limited to this example. For example, when the substrate 21 is the multilayer printed circuit board, the holes 35 may be located within the substrate 21 and may not necessarily have the openings in the front surface of the substrate 21.

The substrate 21 includes an inner surface 35a of each of the plurality of holes 35. The inner surface 35a is an example of an inner edge. The inner surface 35a specifies the corresponding hole 35 and faces in a direction crossing the Z-axis. In another expression, the inner surface 35a faces the corresponding hole 35 and the hole 35 is provided inside of the inner surface 35a.

The inner surface 35a is a generally cylindrical surface extending in the direction along the Z-axis. An end portion of the inner surface 35a in the normal direction along the Z-axis is connected to the first surface 21a. An end portion of the inner surface 35a in the negative direction along the Z-axis is connected to the second surface 21b.

As shown in FIG. 1, the substrate 21 also includes an outer edge 21c. The outer edge 21c is located opposite to the inner surface 35a and faces outside of the substrate 21. The outer edge 21c is a generally cylindrical surface extending in the direction along the Z-axis and connected to the first surface 21a and the second surface 21b. The inner surface 35a is located on an inner side of the substrate 21 further inward of the outer edge 21c.

The first wiring 22 and the second wiring 23 are each formed from a conductor such as copper. The first wiring 22 is provided on the first surface 21a. The second wiring 23 is provided on the second surface 21b.

The first wiring 22 includes a first pattern 41, three second patterns 42, and a third pattern 43. The first to third patterns 41 to 43 are connected to the plurality of vias 24. It is noted that the first wiring 22 may include a pattern that is not connected to the vias 24.

The plurality of vias 24 include a via 24A, three vias 24B, and a via 24C. The vias 24A, 24B, and 24C are substantially identical in shape. Description common to the vias 24A, 24B, and 24C will be given as description of the vias 24 hereinafter. It is noted that the plurality of vias 24 on the wiring board 15 may have different shapes.

The first pattern 41 connects the single via 24A to the three electronic components 16. The three second patterns 42 each connect one of the vias 24B to one of the electronic components 16. The third pattern 43 is connected to the single via 24C.

The first pattern 41 includes a first extension portion 41a, three second extension portions 41b, and a third extension portion 41c. The first extension portion 41a extends from the via 24A in a negative direction along the X-axis (opposite direction to an arrow of the X-axis). The three second extension portions 41b each extend from a terminal connected to one corresponding electronic component 16 in a normal direction along the X-axis (direction indicated by the arrow of the X-axis). The three second extension portions 41b are disposed in a direction along the Y-axis at intervals. The third extension portion 41c extends in the direction along the Y-axis and connects the first extension portion 41a to the three second extension portions 41b. In this way, the first pattern 41 branches off into the three second extension portions 41b.

The three second patterns 42 are disposed in a direction along the Y-axis. The three second patterns 42 each include a fourth extension portion 42a and a fifth extension portion 42b. The fourth extension portion 42a is an example of a first extension portion. The fifth extension portion 42b is an example of a third conductor.

The fourth extension portion 42a extends from one corresponding via 24B in a normal direction along the Y-axis (direction indicated by an arrow of the Y-axis). The normal direction along the Y-axis is the direction along the first surface 21a and is an example of a seventh direction and a 13th direction. The fifth extension portion 42b extends from a terminal connected to one corresponding electronic component 16 in the negative direction along the X-axis and is connected to the fourth extension portion 42a. A pad to which a terminal of, for example, the three-phase brushless motor is connected is provided on the fourth extension portion 42a. The third pattern 43 extends from the via 24C in the normal direction along the X-axis.

The electronic components 16 are each connected to the second extension portion 14b of the first pattern 41 and the fifth extension portion 42b of the second pattern 42. That is, the three second patterns 42 are electrically connected to the first pattern 41 via the corresponding electronic components 16.

As shown in FIG. 2, each via 24 is provided in the hole 35 and connects the first wiring 22 to the second wiring 23. The via 24 includes a film 51, a fill conductor 52, and a pin 53. The film 51 is an example of a first conductor. The fill conductor 52 is an example of a second conductor. The pin 53 is an example of a fourth conductor.

The film 51 is formed from a conductor such as copper similarly to the first wiring 22 and the second wiring 23. It is noted that the film 51 may be formed from a material different from the material of the first wiring 22 and the second wiring 23.

The film 51 is provided on the inner surface 35a of the hole 35. In other words, the film 51 covers the inner surface 35a. The film 51 is formed on the inner surface 35a by, for example, plating or sputtering. It is noted that the film 51 may be formed by another method. Furthermore, the film 51 may cover a part of the inner surface 35a.

The film 51 has a shape according to a shape of the inner surface 35a of the hole 35 and is formed into the cylindrical shape extending in the direction along the Z-axis. The film 51 includes a first end portion 51a and a second end portion 51b. The first end portion 51a is an end portion of the film 51 in the normal direction along the Z-axis and connected to the first wiring 22. The second end portion 51b is an end portion of the film 51 in the negative direction along the Z-axis and connected to the second wiring 23.

In the via 24B shown in FIG. 2, the film 51 is connected to the fourth extension portion 42a of the second pattern 42. In the via 24A shown in FIG. 1, the film 51 is connected to the first extension portion 41a of the first pattern 41. In the via 24C shown in FIG. 1, the film 51 is connected to the third pattern 43.

As shown in FIG. 2, the film 51 electrically connects the first wiring 22 to the second wiring 23 by being connected to the first wiring 22 and the second wiring 23. That is, the film 51 forms a through-hole electrically connected to the first wiring 22 and the second wiring 23.

A thickness T1 of the film 51 is less than a thickness T2 of the first wiring 22. The thickness T1 of the film 51 is a distance between the inner surface 35a of the hole 35 and a front surface of the film 51 covering the inner surface 35a. The thickness T2 of the first wiring 22 is a distance between the first surface 21a and a front surface of the first wiring 22 covering the first surface 21a.

Furthermore, the thickness T1 of the film 51 is less than a thickness T3 of the second wiring 23. The thickness T3 of the second wiring 23 is a distance between the second surface 21b and a front surface of the second wiring 23 covering the second surface 21b.

The thicknesses T1 to T3 often vary depending on positions. In this case, medians of the thicknesses T1 to T3 measured at a plurality of positions hold the abovementioned relationship. That is, the median of the thickness T1 of the film 51 is less than the median of the thickness T2 of the first wiring 22 and less than the median of the thickness T3 of the second wiring 23.

A cross-sectional area of the film 51 orthogonal to the direction along the Z-axis is less than a cross-sectional area of the first wiring 22 orthogonal to an extension direction of the first wiring 22. Furthermore, the cross-sectional area of the film 51 orthogonal to the direction along the Z-axis is less than a cross-sectional area of the second wiring 23 orthogonal to an extension direction of the second wiring 23. It is noted that the cross-sectional area of the film 51 may be larger than the cross-sectional area of the first wiring 22 or may be larger than the cross-sectional area of the second wiring 23.

In the present embodiment, the fill conductor 52 is a solder. The solder is an alloy containing tin and lead. It is noted that the fill conductor 52 may be, for example, an alloy containing a solder or may be a solder into which a conductor such as copper powder is mixed. In this way, the fill conductor 52 may differ from an ordinary solder as long as the fill conductor 52 includes the solder. Moreover, the fill conductor 52 may be a conductor different from the solder such as another metal or a silver paste.

The fill conductor 52 is provided within the hole 35. In other words, the fill conductor 52 is surrounded by the inner surface 35a of the hole 35. The fill conductor 52 comes in contact with the film 51 and the pin 53. The fill conductor 52 is thereby electrically connected to the film 51 and the pin 53. It is noted that the fill conductor 52 may come in contact with a part of the first wiring 22 and a part of the second wiring 23.

The pin 53 is formed from, for example, a conductor such as stainless steel. It is noted that the pin 53 may be formed from copper or another conductor. An electrical resistance of the pin 53 is lower than an electrical resistance of the fill conductor 52. It is noted that the electrical resistances of the pin 53 and the fill conductor 52 are not limited to this example.

The pin 53 includes an insertion portion 53a. The insertion portion 53a is formed into a plate shape that can be accommodated in the hole 35. In other words, the insertion portion 53a is smaller than the hole 35. It is noted that the insertion portion 53a may be formed into another shape such as a rod shape.

The insertion portion 53a is inserted into the hole 35. In other words, the insertion portion 53a is within the hole 35 and surrounded by the inner surface 35a of the hole 35. The insertion portion 53a may be either in contact with the film 51 or apart from the film 51. The fill conductor 52 is interposed between the insertion portion 53a and the film 51. The insertion portion 53a is thereby electrically connected to the film 51 via the fill conductor 52 and fixed to the film 51 by the fill conductor 52. That is, causing the fill conductor 52 to support the insertion portion 53a can restrict the insertion portion 53a from coming off from (or out of) the hole 35.

As described above, each via 24 is provided in the hole 35 and includes the three conductors, that is, the film 51, the fill conductor 52, and the pin 53. A sum of cross-sectional areas of the film 51, the fill conductor 52, and the pin 53, which is a cross-sectional area of each via 24, on the X-Y plane orthogonal to the direction along the Z-axis is larger than the cross-sectional area of the first wiring 22 orthogonal to the extension direction of the first wiring 22. Furthermore, a sum of the cross-sectional areas of the film 51 and the fill conductor 52 on the X-Y plane orthogonal to the direction along the Z-axis is larger than the cross-sectional area of the second wiring 23 orthogonal to the extension direction of the second wiring 23.

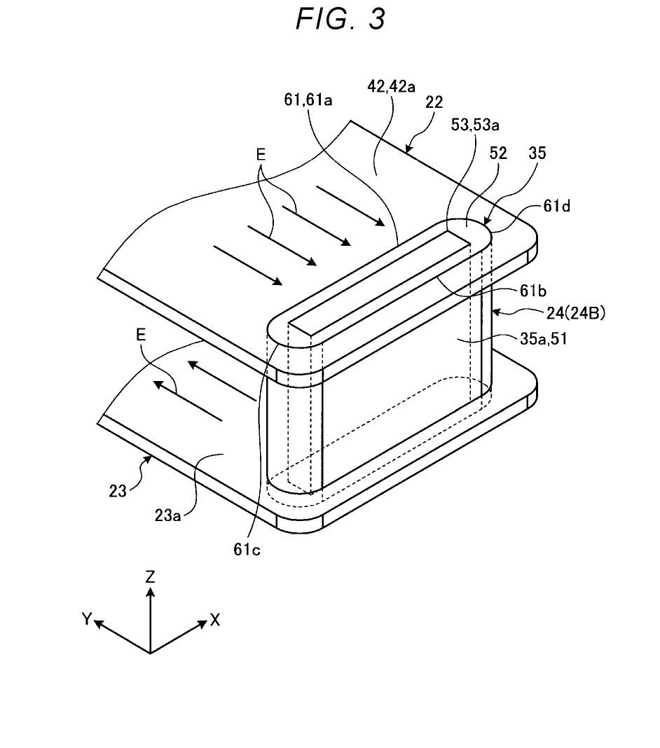

FIG. 3 is a perspective view schematically illustrating a part of the first wiring 22, a part of the second wiring 23, and the via 24B according to the first embodiment. That is, FIG. 3 illustrates a part of the wiring board 15 with the substrate 21 omitted. Furthermore, FIG. 3 illustrates the first wiring 22 with the fifth extension portion 42b omitted. As shown in FIG. 3, the second wiring 23 includes a sixth extension portion 23a. The sixth extension portion 23a is an example of a second extension portion.

As shown in FIG. 2, the sixth extension portion 23a is connected to the second end portion 51b of the film 51 of the via 24B. As shown in FIG. 3, in the first embodiment, the sixth extension portion 23a extends from the via 24B in the normal direction along the Y-axis. The normal direction along the Y-axis is the direction along the second surface 21b.

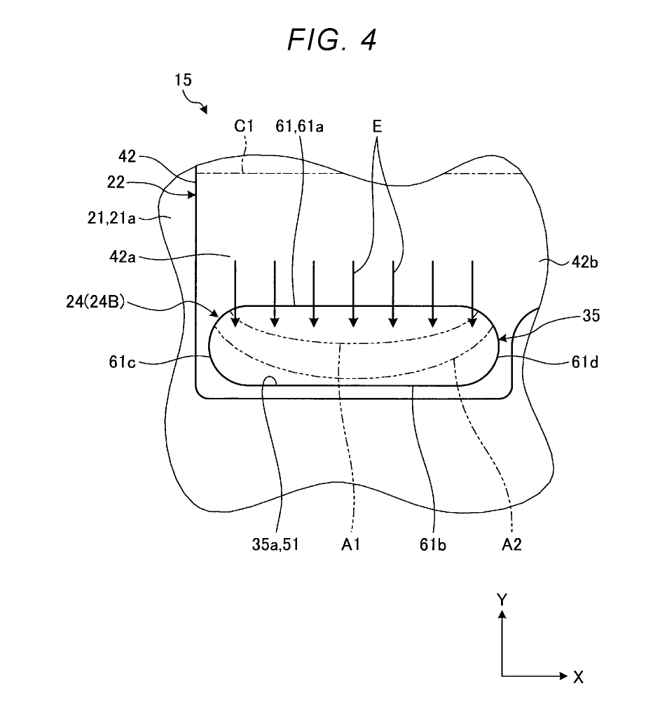

FIG. 4 is a plan view schematically illustrating a part of the wiring board 15 according to the first embodiment. As shown in FIG. 4, the via 24 includes a first portion 61. The first portion 61 of the via 24B extends in the direction along the X-axis. That is, a length of the first portion 61 in the direction along the X-axis is greater than a length of the first portion 61 in the direction along the Y-axis which is orthogonal to the direction along the X-axis and which is along the first surface 21a. The direction along the X-axis includes the normal direction along the X-axis and the negative direction along the X-axis, and is the direction along the first surface 21a. The direction along the X-axis is an example of a third direction, a fifth direction, an eighth direction, and an eleventh direction.

The direction along the X-axis, which is the extension direction of the first portion 61 is orthogonal to (crosses) the normal direction along the Y-axis, is the extension direction of the fourth extension portion 42a. Furthermore, as shown in FIG. 3, the direction along the X-axis, which is the extension direction of the first portion 61 is orthogonal to (crosses) the normal direction along the Y-axis, is the extension direction of the sixth extension portion 23a.

As shown in FIG. 4, the first portion 61 in the first embodiment is formed into an oval (or rounded rectangular) cylindrical shape substantially extending in the direction along the X-axis. Moreover, the hole 35 in which the first portion 61 is provided is formed into an oval slit (elongate hole) shape substantially extending in the direction along the X-axis. It is noted that the first portion 61 may be formed into another shape such as an elliptical cylindrical shape or a rectangular cylindrical shape extending in the direction along the X-axis. In another alternative, the first portion 61 may be formed into a columnar or quadrangular prism shape.

The first portion 61 includes a first edge 61a, a second edge 61b, a third edge 61c, and a fourth edge 61d. Each of the first edge 61a and the second edge 61b is an example of a first major side and a second major side. The first edge 61a and the second edge 61b extend linearly in the direction along the X-axis. It is noted that the first edge 61a and the second edge 61b may include portions extending in other directions as long as the first edge 61a and the second edge 61b extend in the direction along the X-axis as a whole.

The second edge 61b is spaced-apart from the first edge 61a in the negative direction along the Y-axis (opposite direction to the arrow of the Y-axis). A length of the second edge 61b in the direction along the X-axis is substantially equal to a length of the first edge 61a in the direction along the X-axis. It is noted that the length of the second edge 61b in the direction along the X-axis may be smaller than the length of the first edge 61a in the direction along the X-axis.

The third edge 61c and the fourth edge 61d are each formed into a circular arc shape. Each of the third edge 61c and the fourth edge 61d is connected to an either end of the first edge 61a in the direction along the X-axis and an either end of the second edge 61b in the direction along the X-axis.

The length of the first edge 61a in the direction along the X-axis is greater than a length of the third edge 61c in the direction along the Y-axis. In addition, the length of the first edge 61a in the direction along the X-axis is greater than a length of the fourth edge 61d in the direction along the Y-axis.

The first portion 61 of the via 24B is disposed in such a manner that the first edge 61a is oriented toward a center line C1 of the first wiring 22 at a position apart from the center line C1. In other words, a line along the first surface 21a and orthogonal to the first edge 61a crosses the center line C1.

As shown in FIG. 1, the center line C1 is a line connecting centers in the extension direction of the first wiring 22. That is, the center line C1 is determined by plotting centers of the first wiring 22 in the direction orthogonal to the extension direction of the first wiring 22 and connecting the plotted points. Since the first pattern 41 branches off, the center line C1 on the first pattern 41 branches off.

Similarly, each of the vias 24A and 24C includes the first portion 61. The first portion 61 of each of the vias 24A and 24C extends in the direction along the Y-axis. The first portion 61 of each of the vias 24A and 24C is disposed in such a manner that the first edge 61a crosses the center line C1 of the first wiring 22. In other words, the first portion 61 of each of the vias 24A and 24C is disposed in such a manner that the first edge 61a is on both sides of the center line C1 of the first wiring 22.

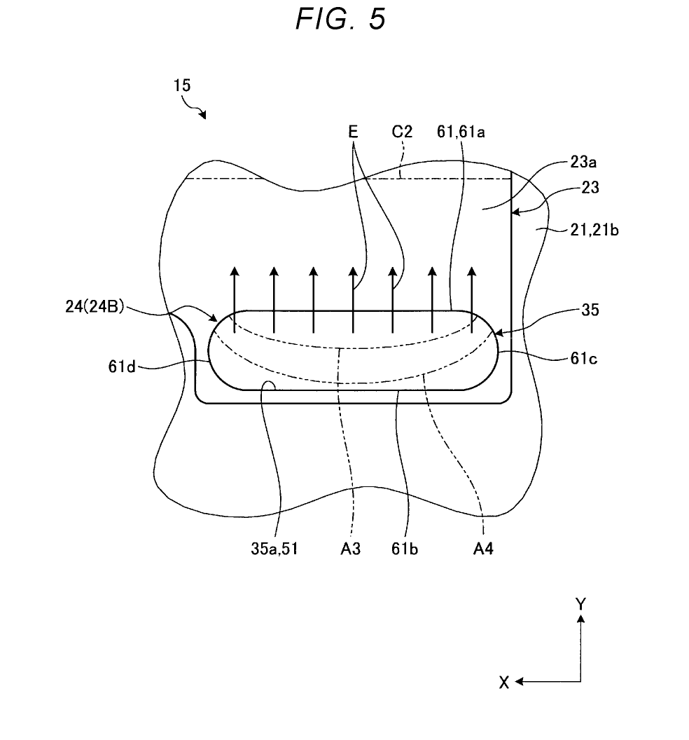

FIG. 5 is a plan view schematically illustrating a part of the second surface 21b of the wiring board 15 according to the first embodiment. As shown in FIG. 5, the first portion 61 of the via 24B is disposed in such a manner that the first edge 61a is oriented toward a center line C2 of the second wiring 23 at a position apart from the center line C2. In other words, a line along the second surface 21b and orthogonal to the first edge 61a crosses the center line C2.

The center line C2 is a line connecting centers in the extension direction of the second wiring 23. That is, the center line C2 is determined by plotting centers of the second wiring 23 in the direction orthogonal to the extension direction of the second wiring 23 and connecting the plotted points.

As shown in FIG. 3, the fourth extension portion 42a extends from the first edge 61a in the normal direction along the Y-axis. That is, the fourth extension portion 42a extends in the direction orthogonal to (crossing) the extension direction of the first edge 61a. The sixth extension portion 23a similarly extends from the first edge 61a in the normal direction along the Y-axis.

As shown in FIG. 1, when the three-phase brushless motor, for example, is driven, a current E that is a three-phase alternating-current is supplied from the via 24A to the first wiring 22, passes through the three vias 24B, and flows through the second wiring 23. That is, the film 51, the fill conductor 52, and the pin 53 of each via 24B feed the current E from the first wiring 22 through the second wiring 23. The current E will be described specifically hereinafter. It is noted that the current E is not limited to the following description.

The current E flows from the via 24A through the three second extension portions 41b while passing through the first extension portion 41a and the third extension portion 41c. The current E flows from the second extension portions 41b through the fifth extension portions 42b while passing through the electronic components 16 that are the switching elements.

The current E is fed from the fifth extension portions 42b through the vias 24B while passing through the fourth extension portions 42a. That is, each fifth extension portion 42b feeds the current E through the film 51, the fill conductor 52, and the pin 53 while passing the current E through the fourth extension portion 42a. Each fourth extension portion 42a connects the fifth extension portion 42b to the film 51.

As shown in FIG. 4, the current E flows from the fourth extension portion 42a through the via 24B in the negative direction along the Y-axis. In other words, the current E flows from the first wiring 22 through the film 51 in the negative direction along the Y-axis.

As described above, each hole 35 and each first portion 61 extend in the direction along the X-axis. Moreover, the first edge 61a of the first portion 61 extends in the direction along the X-axis. The direction along the X-axis crosses the negative direction along the Y-axis that is the direction in which the current E flows from the first wiring 22 through the film 51.

The first edge 61a is closer than the second edge 61b to a connection section between the fourth extension portion 42a and the fifth extension portion 42b. The first edge 61a is oriented toward the current E that flows from the connection section between the fourth extension portion 42a and the fifth extension portion 42b toward the film 51. In another expression, the current E flows toward the first edge 61a.

The current E flows from portions close to the first edge 61a through the via 24B. Owing to this, a current distribution is generated in the via 24B. For example, a current density in a region A1 close to the first edge 61a is higher than a current density in a region A2 farther from the first edge 61a.

The length of the first edge 61a is greater than the length of the third edge 61c and greater than the length of the fourth edge 61d. Owing to this, the region A1 having the higher current density is provided relatively widely. Therefore, the current density in the region A1 becomes low, as compared with a case, for example, where the length of the first edge 61a is smaller than the length of the third edge 61c. It is thereby possible to reduce Joule heat generated in the region A1 of the via 24B.

Furthermore, as described above, the sum of the cross-sectional areas of the film 51, the fill conductor 52, and the pin 53, which is the cross-sectional area of the via 24B, is greater than the cross-sectional area of the first wiring 22. Owing to this, Joule heat generated in the via 24B is lower than Joule heat generated in the first wiring 22. It is noted that the Joule heat generated in the via 24B may be higher than the Joule heat generated in the first wiring 22 due to, for example, the electrical resistance in the via 24B.

As shown in FIG. 3, the current E passes through the via 24B and flows through the sixth extension portion 23a of the second wiring 23. The sixth extension portion 23a extends from the first edge 61a in the normal direction along the Y-axis. Owing to this, the current E flows from the portions close to the first edge 61a through the sixth extension portion 23a, and a current distribution is generated in the via 24B similarly to a case where the current E enters the via 24B.

As shown in FIG. 5, for example, a current density in a region A3 close to the first edge 61a is higher than a current density in a region A4 far from the first edge 61a. The length of the first edge 61a is greater than the length of the third edge 61c and greater than the length of the fourth edge 61d. Owing to this, the region A3 having the higher current density is provided relatively widely. Therefore, the current density in the region A3 becomes low, as compared with a case, for example, where the length of the first edge 61a is smaller than the length of the third edge 61c. It is thereby possible to keep down Joule heat generated in the region A3 of the via 24B.

Each of the vias 24 of the electronic apparatus 10 described so far is manufactured, for example, as described below. It is noted that a manufacturing method of the vias 24 is not limited to the example described below.

First, the hole 35 is bored in the substrate 21 by, for example, a drill. It is noted that the hole 35 may be bored by another means. Next, the film 51 is formed on the inner surface 35a of the hole 35 by, for example, plating or sputtering. The first wiring 22 and the second wiring 23 may be formed simultaneously with the film 51.

Next, the insertion portion 53a of the pin 53 and the solder paste are inserted into the hole 35. For example, the insertion portion 53a of the pin 53 is inserted into the hole 35 filled with the solder paste in advance. The solder paste thereby holds the pin 53 to suppress the pin 53 from coming off from the hole 35.

Next, the solder paste is subjected to reflow in a furnace, whereby the fill conductor 52 that is the solder is formed within the hole 35 in a state in which the fill conductor 52 comes in contact with the film 51 and the pin 53. It is noted that a formation method of the fill conductor 52 is not limited to the reflow method but may be a flow method. Through the abovementioned processes, the via 24 is manufactured.

In the electronic apparatus 10 according to the first embodiment described so far, the film 51 provided on the inner surface 35a of each hole 35 is thinner than the first wiring 22 and thinner than the second wiring 23. Owing to this, the current E that can flow through the first wiring 22 and the second wiring 23 is higher than the current E that can flow through the film 51. On the other hand, the fill conductor 52 is surrounded by the inner surface 35a and electrically connected to the film 51. That is, the cross-sectional area of the via 24 within the hole 35 is enlarged by the fill conductor 52. Therefore, the high current (current E) that can be fed through the first wiring 22 and the second wiring 23 can be fed through the via 24. In another expression, the current density of the current E flowing through the first wiring 22 and the second wiring 23 is suppressed from considerably increasing in the via 24. It is thereby possible to suppress the film 51 from being damaged due to flow of the current E. Moreover, the current E that can be fed through an ordinary through-hole is lower than the current E that can be fed through the via 24 in the present embodiment. Owing to this, when a predetermined current E is fed from the first wiring 22 through the second wiring 23 by means of the ordinary through-hole, a plurality of through-holes are provided in the substrate 21. In the module 11 in the present embodiment, it is possible to electrically connect the first wiring 22 to the second wiring 23 in a smaller space than that used when the plurality of through-holes connect the first wiring 22 to the second wiring 23. Therefore, it is possible to minimize the size of the substrate 21 and suppress a space enabling the electronic components 16 and the first and second wirings 22 and 23 to be mounted on the substrate 21 from being made narrow.

The first portion 61 extends in the direction along the X-axis that is along the first surface 21a and that crosses the negative direction along the Y-axis in which the current E flows from the first wiring 22 through the film 51. Owing to this, the current E flows through the via 24 from the wide range or area. It is thereby possible to make more uniform the current distribution in the via 24 and suppress generation of a portion having a considerably high current density in the via 24. Therefore, it is possible to suppress the film 51 from being damaged due to flow of the current E.

The first portion 61 includes the first edge 61a extending in the direction along the X-axis and is disposed in such a manner that the first edge 61a crosses the center line C1 of the first wiring 22 or is oriented toward the center line C1 of the first wiring 22. Since the current E flows generally along the center line C, the current E flows from portions along the first edge 61a extending in a longitudinal direction of the first portion 61 through the film 51. Therefore, the current E flows through the via 24 from the wide range, the current distribution is made more uniform in the via 24, and generation of the portion having the considerably high current density is suppressed in the via 24. Therefore, it is possible to suppress the film 51 from being damaged due to flow of the current E.

The fourth extension portion 42a of the first wiring 22 connected to the film 51 extends in the normal direction along the Y-axis. The first portion 61 extends in the direction along the X-axis which crosses the normal direction along the Y-axis. Owing to this, the current E flows through the via 24 from the wide range or area. It is thereby possible to make more uniform the current distribution in the via 24 and suppress generation of a portion having a considerably high current density in the via 24. Therefore, it is possible to suppress the film 51 from being damaged due to flow of the current E.

The fill conductor 52 includes the solder. It is thereby possible to easily provide, within the hole 35, the fill conductor 52 electrically connected to the film 51.

The pin 53 includes the insertion portion 53a surrounded by the inner surface 35a of the hole 35 and is electrically connected to the film 51 via the fill conductor 52 including the solder. By disposing the insertion portion 53a within the hole 35 to be surrounded by the inner surface 35a, a space which is between the insertion portion 53a and the film 51 and in which the fill conductor 52 is interposed therebetween is made small. The fill conductor 52 including the solder thereby easily adheres to the insertion portion 53a and the film 51 by surface tension, thereby making it possible to easily provide, within the hole 35, the fill conductor 52 electrically connected to the film 51.

The electrical resistance of the pin 53 is lower than the electrical resistance of the fill conductor 52 including the solder. By electrically connecting such a pin 53 to the film 51 via the fill conductor 52, it is possible to feed the higher current E through the via 24. It is thereby possible to suppress the film 51 from being damaged due to flow of the current E.

The total cross-sectional area of the via 24 orthogonal to the extension direction of the inner surface 35a is larger than the cross-sectional area of the first wiring 22 orthogonal to the extension direction of the first wiring 22. The high current (current E) that can be fed through the first wiring 22 and the second wiring 23 can be thereby fed through the via 24. Therefore, it is possible to suppress the film 51 from being damaged due to flow of the current E.

### Second Embodiment

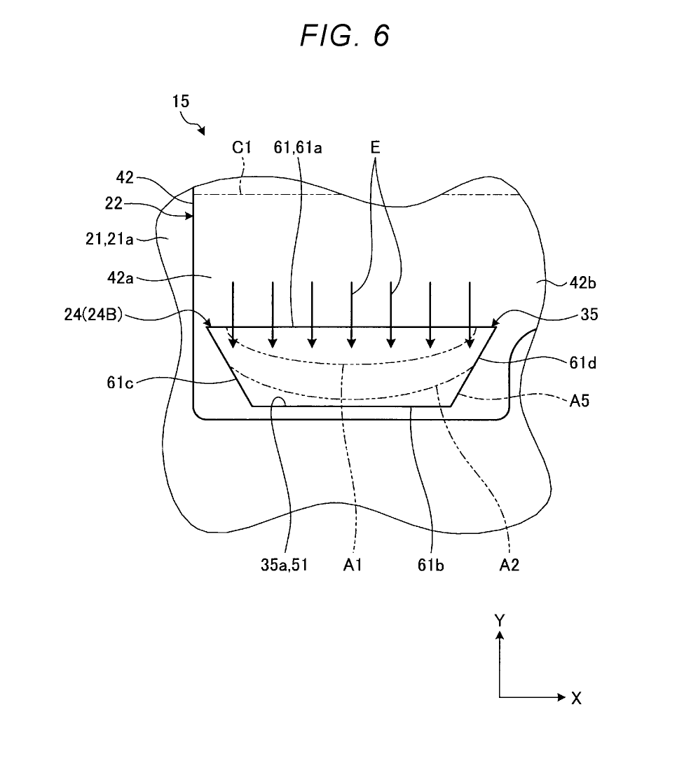

A second embodiment will be described hereinafter with reference to FIG. 6. It is noted that constituent elements having similar functions as those already described are denoted by the same reference signs as those of the already-described constituent elements and, further, description thereof is often omitted in a plurality of embodiments to be described below, for brevity. Moreover, all functions and properties are not necessarily common to a plurality of constituent elements denoted by the same reference sign, and the plurality of constituent elements may have, or exhibit different functions and properties, depending on the embodiments.

FIG. 6 is a plan view schematically illustrating a part of the wiring board 15 according to the second embodiment. As shown in FIG. 6, in the second embodiment, the first portion 61 of each via 24B is formed into a generally trapezoidal slit shape extending in the direction along the X-axis.

The first edge 61 and the second edge 61b of the first portion 61 extend linearly in the direction along the X-axis similarly to the first embodiment. The length of the first edge 61a in the direction along the X-axis is greater than the length of the second edge 61b in the direction along the X-axis.

Each of the third edge 61c and the fourth edge 61d is formed linearly to be connected to an either end of the first edge 61a in the direction along the X-axis and an either end of the second edge 61b in the direction along the X-axis. The third edge 61c and the fourth edge 61d become closer to each other as being closer to the second edge 61b from the first edge 61a.

The first portion 61 including the first to fourth edges 61a to 61d is formed into a shape such that a length in the direction along the X-axis becomes smaller from the first edge 61a toward the negative direction along the Y-axis. The negative direction along the Y-axis is the opposite direction to the extension direction of the fourth extension portion 42a and is an example of a twelfth direction. The negative direction along the Y-axis is the direction along the first surface 21a and orthogonal to the direction along the X-axis in which the first edge 61a extends.

As described above, the first portion 61 extends in the direction along the X-axis. Owing to this, the length of the via 24B in the direction along the X-axis is greater than the length of the via 24B in the negative direction along the Y-axis. It is noted that that dimensions of the via 24B are not limited to this example.

The current E flows from portions close to the first edge 61a through the via 24B similarly to the first embodiment. Owing to this, the current density in the region A1 close to the first edge 61a is higher than the current density in the region A2 far from the first edge 61a.

The region A1 having the higher current density is generated along the first edge 61a and spreads from a center of the first edge 61a in the direction along the X-axis. Owing to this, the region A1 takes on a generally semi-elliptical shape or a generally trapezoidal shape such that a length in the direction along the X-axis becomes smaller from the first edge 61a toward the negative direction along the Y-axis. Similarly, the region A2 having the relatively low current density takes on a generally semi-elliptical shape or a generally trapezoidal shape. The shape of the via 24B such that the length in the direction along the X-axis becomes smaller from the first edge 61a toward the negative direction along the Y-axis is close to the shapes of the regions A1 and A2 through which the current flows.

Meanwhile, a region A5 having a lower current density is often generated in the via 24B. The region A5 is farther than the region A2 from the first edge 61a. Since the shape of the via 24B is close to the shapes of the regions A1 and A2, the region A5 becomes small and the current distribution in the via 24B is made more uniform.

In the electronic apparatus 10 in the second embodiment described so far, each via 24 includes the first edge 61a extending in the direction along the X-axis, and is formed into the shape such that the length in the direction along the X-axis becomes smaller from the first edge 61a toward the negative direction along the Y-axis that is orthogonal to the direction along the first surface 21a and along the X-axis. The first wiring 22 includes the fourth extension portions 42a each extending from the first edge 61a in the normal direction along the Y-axis opposite to the negative direction along the Y-axis. The fourth extension portion 42a connects the film 51 to the fifth extension portion 42b feeding the current E through the film 51 while passing the current E through the fourth extension portion 42a. Owing to this, the current E flows through the via 24 from the wide range. It is thereby possible to make more uniform the current distribution in the via 24 and suppress generation of a portion having a considerably high current density in the via 24. Therefore, it is possible to suppress the film 51 from being damaged due to flow of the current E. Furthermore, the regions A1 and A2 in which the current E flows through the via 24 each spread in the generally semi-elliptical shape or the generally trapezoidal shape with the first edge 61a as a center. Forming the via 24 into the shape such that the length in the direction along the X-axis becomes smaller toward the negative direction along the Y-axis can make smaller the region A5 through which the current E does not flow.

The length of the via 24 in the direction along the X-axis is greater than the length of the via 24 in the negative direction along the Y-axis. Owing to this, the current E flows through the via 24 from the wider range or area. It is thereby possible to make more uniform the current distribution in the via 24 and suppress generation of a portion having a considerably high current density in the via 24. Therefore, it is possible to suppress the film 51 from being damaged due to flow of the current E.

### Third Embodiment

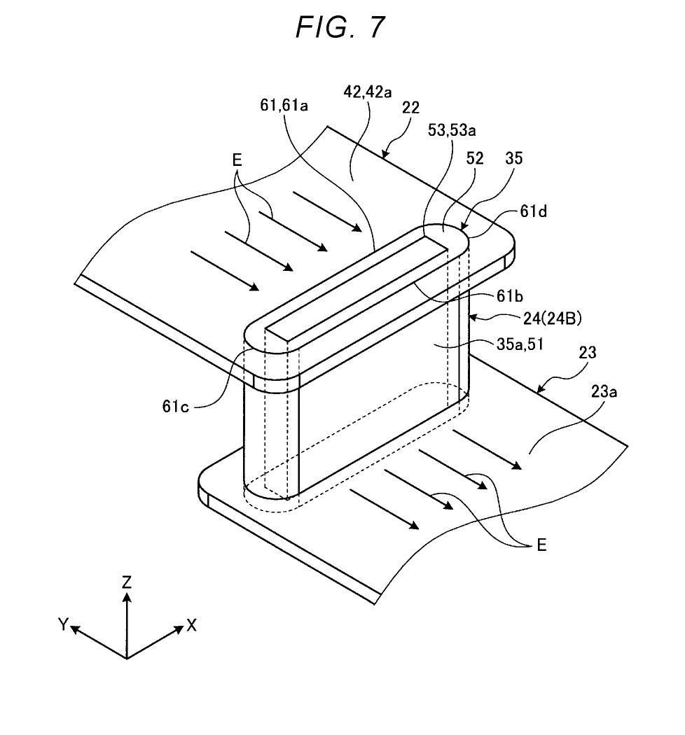

A third embodiment will be described hereinafter with reference to FIG. 7. FIG. 7 is a perspective view schematically illustrating a part of the first wiring 22, a part of the second wiring 23, and the via 24B according to the third embodiment.

As shown in FIG. 7, in the third embodiment, the sixth extension portion 23a extends from the second edge 61b of the first portion 61 of each via 24B in the negative direction along the Y-axis. That is, in the third embodiment, the fourth extension portion 42a and the sixth extension portion 23a extend from the via 24B in directions different from each other.

The current E passes through the via 24B and flows through the sixth extension portion 23a of the second wiring 23. The sixth extension portion 23a extends from the second edge 61b in the negative direction along the Y-axis. Owing to this, the current E flows from portions close to the second edge 61b through the sixth extension portion 23a, and a current distribution is generated in the via 24B. For example, a current density in a region close to the second edge 61b is higher than a current density in a region farther from the second edge 61b.

The length of the second edge 61b in the direction along the X-axis is substantially equal to the length of the first edge 61a in the direction along the X-axis similarly to the first embodiment. Owing to this, the length of the second edge 61b is greater than the length of the third edge 61c and greater than the length of the fourth edge 61d.

Since the second edge 61b is long, the region having the higher current density is provided relatively widely in the via 24B. Therefore, the current density in the region becomes low, as compared with, for example, where the length of the second edge 61b is smaller than the length of the third edge 61c. It is thereby possible to keep down Joule heat generated in the via 24B.

In the electronic apparatus 10 in the third embodiment described so far, the length of the second edge 61b in the direction along the X-axis is substantially equal to the length of the first edge 61a in the direction along the X-axis. The sixth extension portion 23a extends from the second edge 61b. Owing to this, the current E flows through the second wiring 23 from a wide range of the via 24. It is thereby possible to make more uniform the current distribution in the via 24 and suppress generation of a portion having a considerably high current density in the via 24. Therefore, it is possible to suppress the film 51 from being damaged due to flow of the current E.

### Fourth Embodiment

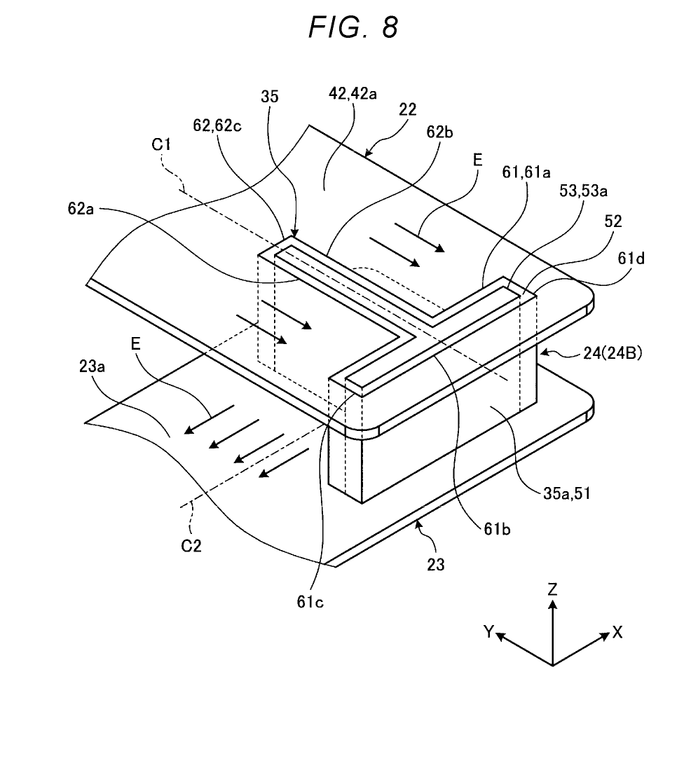

A fourth embodiment will be described hereinafter with reference to FIG. 8. FIG. 8 is a perspective view schematically illustrating a part of the first wiring 22, a part of the second wiring 23, and the via 24B according to the fourth embodiment. As shown in FIG. 8, each via 24 in the fourth embodiment includes the first portion 61 and a second portion 62.

In the fourth embodiment, the first portion 61 is disposed in such a manner that the first edge 61a crosses the center line C1 of the first wiring 22. In other words, the first portion 61 is disposed in such a manner that the first edge 61a extends on both sides of the center line C1 of the first wiring 22. It is noted that the first portion 61 may be disposed in such a manner that the first edge 61a is oriented toward the center line C1 of the first wiring 22 at a position apart from the center line C1 similarly to the first embodiment.

In the fourth embodiment, the first portion 61 of the via 24B is formed into a rectangular shape extending in the direction along the X-axis. It is noted that the first portion 61 may be formed into another shape. The first edge 61a and the second edge 61b extend linearly in the direction along the X-axis. Each of the third edge 61c and the fourth edge 61d is formed linearly to extend in the direction along the Y-axis and to be connected to an either end of the first edge 61a in the direction along the X-axis and an either end of the second edge 61b in the direction along the X-axis.

The second portion 62 extends in the normal direction along the Y-axis and is formed into a rectangular shape connected to a general center of the first edge 61a. That is, the via 24 including the first portion 61 and the second portion 62 is formed into a general T-shape. The direction along the Y-axis includes the normal direction along the Y-axis and the negative direction along the Y-axis, is the direction along the second surface 21b, and is an example of a fourth direction, a sixth direction, and a tenth direction. It is noted that the second portion 62 may be formed into another shape such as an oval shape or an elliptical shape.

The second portion 62 includes a fifth edge 62a, a sixth edge 62b, and a seventh edge 62c. The fifth edge 62a is an example of a second edge. The fifth edge 62a and the sixth edge 62b extend linearly in the direction along the Y-axis. It is noted that the fifth edge 62a and the sixth edge 62b may include portions extending in other directions as long as the fifth edge 62a and the sixth edge 62b extend in the direction along the Y-axis as a whole.

The sixth edge 62b is apart from the fifth edge 62a in the normal direction along the X-axis. A length of the sixth edge 62b in the direction along the Y-axis is substantially equal to a length of the fifth edge 62a in the direction along the Y-axis. It is noted that the length of the sixth edge 62b in the direction along the Y-axis may be less than the length of the fifth edge 62a in the direction along the Y-axis.

The seventh edge 62c extends in the direction along the X-axis, and is connected to an end of the fifth edge 62a in the normal direction along the Y-axis and an end of the sixth edge 62b in the normal direction along the Y-axis. The length of the fifth edge 62a in the direction along the Y-axis is greater than a length of the seventh edge 62c in the direction along the X-axis.

In the fourth embodiment, the sixth extension portion 23a extends from the via 24B in the negative direction along the X-axis. That is, the sixth extension portion 23a is connected to the film 51 and extends from the film 51 in the negative direction along the X-axis. The negative direction along the X-axis is the direction along the second surface 21b and is an example of a ninth direction.

As described above, the second portion 62 extends in the normal direction along the Y-axis orthogonal to (crossing) the negative direction along the X-axis that is an extension direction of the sixth extension portion 23a. It is noted that the extension direction of the second portion 62 may obliquely cross the extension direction of the sixth extension portion 23a.

The second portion 62 is disposed in such a manner that the fifth edge 62a crosses the center line C2 of the second wiring 23. In other words, the second portion 62 is disposed in such a manner that the fifth edge 62a strides over the center line C2 of the second wiring 23. It is noted that the second portion 62 may be disposed in such a manner that the fifth edge 62a is oriented toward the center line C2 of the second wiring 23 at a position apart from the center line C2.

The current E flows from the fourth extension portion 42a through the via 24B in the negative direction along the Y-axis. The first portion 61 and the first edge 61a extend in the direction along the X-axis. The current E flows through the second portion 62 of the via 24B and flows from portions close to the first edge 61a through the first portion 61 of the via 24B.

A current distribution is generated in the first portion 62 of the via 24B. For example, a current density in a region close to the first edge 61a is higher than a current density in a region far from the first edge 61a.

The length of the first edge 61a is greater than the length of the third edge 61c and greater than the length of the fourth edge 61d. Owing to this, the region having the higher current density is provided relatively widely in the first portion 61 of the via 24B. Therefore, it is possible to keep down Joule heat generated in the via 24B similarly to the first embodiment.

The current E passes through the via 24B and flows through the sixth extension portion 23a of the second wiring 23. The current E flows from the film 51 through the second wiring 22 in the negative direction along the X-axis. That is, the second portion 62 extends in the normal direction along the Y-axis which is the direction orthogonal to (crossing) the direction in which the current E flows from the film 51 of the via 24B through the second wiring 23.

The sixth extension portion 23a extends from the fifth edge 62a in the negative direction along the X-axis. Owing to this, the current E flows from the portions close to the fifth edge 62a through the sixth extension portion 23a, and a current distribution is generated in the via 24B similarly to a case where the current E enters the via 24B. For example, a current density in a region close to the fifth edge 62a is higher than a current density in a region far from the fifth edge 62a.

The length of the fifth edge 62a is greater than the length of the seventh edge 62c. Owing to this, the region having the higher current density is provided relatively widely. Therefore, the current density in the region becomes low, as compared with, for example, where the length of the fifth edge 62a is less than the length of the seventh edge 62c. It is thereby possible to keep down Joule heat generated in the via 24B.

In the electronic apparatus 10 in the fourth embodiment described so far, the second portion 62 of each via 24 extends in the normal direction along the Y-axis that is along the second surface 21b and that crosses the direction in which the current E flows from the film 51 through the second wiring 23. Owing to this, the current E flows through the second wiring 23 from a wide range of the via 24. It is thereby possible to make more uniform the current distribution in the via 24 and suppress generation of a portion having a considerably high current density in the via 24. Therefore, it is possible to suppress the film 51 from being damaged due to flow of the current E.

The second portion 62 of the via 24 includes the fifth edge 62a extending in the direction along the Y-axis, and is disposed in such a manner that the fifth edge 62a crosses the center line C2 of the second wiring 23 or is oriented toward the center line C2 of the second wiring 23. The current E thereby flows from the portions along the fifth edge 62a extending in a longitudinal direction of the second portion 62 through the second wiring 23. Therefore, the current E flows through the second wiring 23 from the wide range, the current distribution is made more uniform in the via 24, and generation of the portion having the considerably high current density is suppressed in the via 24. Therefore, it is possible to suppress the film 51 from being damaged due to flow of the current E.

The sixth extension portion 23a of the second wiring 23 connected to the film 51 extends in the negative direction along the X-axis. The second portion 62 of the via 24 extends in the normal direction along the Y-axis that is along the second surface 21b and that crosses the negative direction along the X-axis. Owing to this, the current E flows through the second wiring 23 from a wide range of the via 24. It is thereby possible to make the current distribution more uniform in the via 24 and suppress generation of a portion having a considerably high current density in the via 24. Therefore, it is possible to suppress the film 51 from being damaged due to flow of the current E.

### Fifth Embodiment

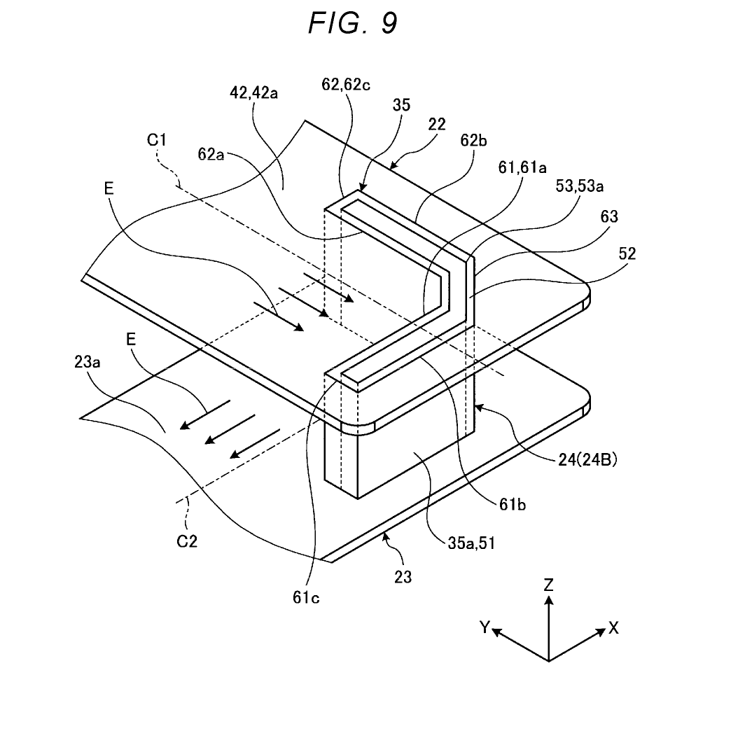

A fifth embodiment will be described hereinafter with reference to FIG. 9. FIG. 9 is a perspective view schematically illustrating a part of the first wiring 22, a part of the second wiring 23, and the via 24B according to the fifth embodiment. As shown in FIG. 9, each via 24 in the fifth embodiment includes the first portion 61, the second portion 62, and a third portion 63.

In the fifth embodiment, the first portion 61 of the via 24B is formed into a rectangular shape extending in the direction along the X-axis similarly to the fourth embodiment. The first portion 61 includes the first edge 61a, the second edge 61b, and the third edge 61c. The first edge 61a and the second edge 61b extend linearly in the direction along the X-axis. The third edge 61c is formed linearly to extend in the direction along the Y-axis, and to be connected to an end of the first edge 61a in the negative direction along the X-axis and to an end of the second edge 61b in the negative direction along the X-axis.

The second portion 62 is formed into a rectangular shape extending in the direction along the Y-axis. The second portion 62 includes the fifth edge 62a, the sixth edge 62b, and the seventh edge 62c. The fifth edge 62a and the sixth edge 62b extend linearly in the direction along the Y-axis. The seventh edge 62c is connected to the end of the fifth edge 62a in the normal direction along the Y-axis and to the end of the sixth edge 62b in the normal direction along the Y-axis.

The third portion 63 extends in a direction along the first surface 21a and inclined at 45 degrees with respect to the X-axis. The third portion 63 is connected to an end of the first portion 61 in the normal direction along the X-axis and to an end of the second portion 62 in the negative direction along the Y-axis. The via 24 including such first to third portions 61 to 63 is formed into a generally L-shape.

Similarly to the fourth embodiment, the sixth extension portion 23a extends from the via 24B in the negative direction along the X-axis. The second portion 62 extends in the normal direction along the Y-axis orthogonal to (crossing) the negative direction along the X-axis that is the extension direction of the sixth extension portion 23a.

In the fifth embodiment, the first portion 61 is disposed in such a manner that the first edge 61a crosses the center line C1 of the first wiring 22. Furthermore, the second portion 62 is disposed in such a manner that the fifth edge 62a crosses the center line C2 of the second wiring 23.

In the fifth embodiment, the first portion 61 may be an example of the second portion and the second portion 62 may be an example of the first portion. In this case, the first portion 61 is disposed in such a manner that the first edge 61a is oriented toward the center line C2 of the second wiring 23 at a position apart from the center line C2. Furthermore, the second portion 62 is disposed in such a manner that the fifth edge 62a is oriented toward the center line C1 of the first wiring 22 at a position apart from the center line C1.

The current E flows from the fourth extension portion 42a through the via 24B in the negative direction along the Y-axis. The current E flows from portions close to the first edge 61a through the first portion 62 of the via 24B. A current distribution is thereby generated in the first portion 62 of the via 24B. For example, a current density in a region close to the first edge 61a is higher than a current density in a region far from the first edge 61a.

The length of the first edge 61a is greater than the length of the third edge 61c. Owing to this, the region having the higher current density is provided relatively widely in the first portion 61 of the via 24B. Therefore, it is possible to keep down Joule heat generated in the via 24B similarly to the first embodiment.

The current E passes through the via 24B and flows through the sixth extension portion 23a of the second wiring 23. The current E flows from portions close to the fifth edge 62a through the sixth extension portion 23a of the second wiring 23 in the negative direction along the X-axis. Owing to this, a current distribution is generated in the via 24B similarly to a case where the current E enters the via 24B. For example, a current density in a region close to the fifth edge 62a is higher than a current density in a region far from the fifth edge 62a.

The length of the fifth edge 62a is greater than the length of the seventh edge 62c. Owing to this, the region having the higher current density is provided relatively widely. Therefore, the current density in the region becomes low, as compared with, for example, where the length of the fifth edge 62a is less than the length of the seventh edge 62c. It is thereby possible to keep down Joule heat generated in the via 24B.

In the electronic apparatus 10 in the fifth embodiment described so far, the third portion 63 connects one end of the first portion 61 in the normal direction along the X-axis to one end of the second portion 62 in the negative direction along the Y-axis. The third portion 63 extends in the direction obliquely crossing both the extension direction of the first portion 61 and the extension direction of the second portion 62. It is thereby possible to suppress generation of concentration of the current E in the via 24, as compared with a case where the first portion 61 and the second portion 62 orthogonal to each other are directly connected to each other.

### Sixth Embodiment

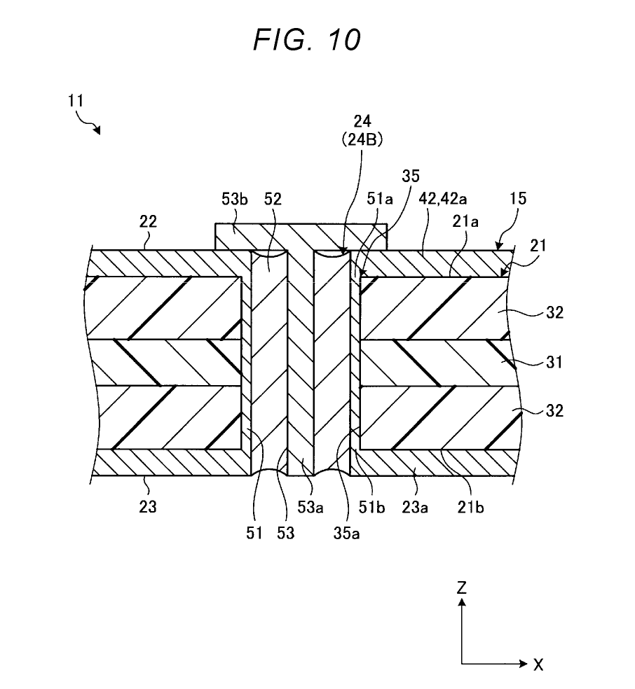

A sixth embodiment will be described hereinafter with reference to FIG. 10. FIG. 10 is a cross-sectional view schematically illustrating the module 11 according to the sixth embodiment. As shown in FIG. 10, the pin 53 in the sixth embodiment includes the insertion portion 53a and a support portion 53b.

The support portion 53b is located outside of the hole 35 and formed into a rod shape or a plate shape spreading on the X-Y plane. The insertion portion 53a is connected to a generally center of the support portion 53b. That is, the pin 53 including the insertion portion 53a and the support portion 53b is formed into a generally T-shape. It is noted that an end portion of the support portion 53b may be connected to the insertion portion 53a and the pin 53 may be formed into a generally L-shape.

In the present embodiment, the support portion 53b is connected to an end portion of the insertion portion 53a in the normal direction along the Z-axis. The support portion 53b is connected to, for example, the first surface 21a or the first wiring 22. The support portion 53b is directly supported by the first surface 21a or supported by the first surface 21a via the first wiring 22.

The support portion 53b may be alternatively connected to an end portion of the insertion portion 53a in the negative direction along the Z-axis. In this alternative, the support portion 53b comes in contact with, for example, the second surface 21b or the second wiring 23. The support portion 53b is directly supported by the second surface 21b or supported by the second surface 21b via the second wiring 23.

In the electronic apparatus 10 in the sixth embodiment described so far, the support portion 53b of the pin 53 is connected to the insertion portion 53a, located outside of the hole 35, and supported by either the first surface 21a or the second surface 21b. It is thereby possible to hold the pin 53 in a state in which the insertion portion 53a is disposed within the hole 35, without a special jig.

In the plurality of embodiments described so far, the extension direction of the fourth extension portion 42a is parallel to the direction in which the current E flows from the first wiring 22 through the film 51. Furthermore, the extension direction of the sixth extension portion 23a is parallel to the direction in which the current E flows from the film 51 through the second wiring 23. However, the extension direction of the fourth extension portion 42a may differ from the direction in which the current E flows from the first wiring 22 through the film 51. Moreover, the extension direction of the sixth extension portion 23a may differ from the direction in which the current E flows from the film 51 through the second wiring 23.

According to at least one embodiment described so far, the second conductor is surrounded by the inner edge of the substrate and electrically connected to the first conductor thinner than the first wiring and thinner than the second wiring. It is thereby possible to suppress the first conductor from being damaged due to flow of the current.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions. The accompanying claims and their equivalents are intended to cover such forms or modifications as would fall within the scope and spirit of the inventions.

1. A module, comprising:
a substrate including a first surface facing a first direction, a second surface facing a second direction opposite to the first direction, and an inner surface of a hole extending between the first surface and the second surface;
a first wiring provided on the first surface;
a second wiring provided on the second surface; and
an interlayer connection section including a first conductor provided on the inner surface, the first conductor connected to the first wiring and the second wiring, the first conductor being thinner than the first wiring and thinner than the second wiring, and a second conductor disposed in the hole and electrically connected to the first conductor.

2. The module according to claim 1, wherein
the first conductor is configured to feed a current from the first wiring through the second wiring, and
the interlayer connection section includes a first portion extending in a third direction along the first surface and crossing a direction in which the current flows from the first wiring through the first conductor.

3. The module according to claim 2, wherein
the interlayer connection section includes a second portion extending in a fourth direction along the second surface and crossing a direction in which the current flows from the first conductor through the second wiring.

4. The module according to claim 1, wherein
the first conductor is configured to feed a current from the first wiring through the second wiring,
the interlayer connection section includes a first portion extending in a fifth direction along the first surface, and
the first portion includes a first edge extending in the fifth direction, and is disposed in such a manner that the first edge either crosses a center line of the first wiring or is oriented toward the center line of the first wiring.

5. The module according to claim 4, wherein
the interlayer connection section includes a second portion extending in a sixth direction along the second surface, and
the second portion includes a second edge extending in the sixth direction, and is disposed in such a manner that the second edge either crosses a center line of the second wiring or is oriented toward the center line of the second wiring.

6. The module according to claim 1, wherein
the first conductor is configured to feed a current from the first wiring through the second wiring,
the first wiring includes a first extension portion extending in a seventh direction along the first surface and connected to the first conductor, and
the interlayer connection section includes a first portion extending in an eighth direction along the first surface and crossing the seventh direction.

7. The module according to claim 6, wherein
the second wiring includes a second extension portion extending in a ninth direction along the second surface and connected to the first conductor, and
the interlayer connection section includes a second portion extending in a tenth direction along the second surface and crossing the ninth direction.

8. The module according to claim 1, wherein
the interlayer connection section includes an edge extending in an eleventh direction along the first surface, and is formed into a shape such that a length in the eleventh direction becomes smaller from the edge toward a twelfth direction along the first surface and orthogonal to the eleventh direction,
the first conductor is configured to feed a current from the first wiring through the second wiring, and
the first wiring includes a first extension portion extending from the edge in a thirteenth direction opposite to the twelfth direction, and
the first extension portion connects the first conductor to a third conductor configured to pass the current through the first extension portion and to feed the current through the first conductor.

9. The module according to claim 8, wherein
a length of the interlayer connection section in the eleventh direction is greater than a length of the interlayer connection section in the twelfth direction.

10. The module according to claim 9, wherein
the second conductor includes a solder.

11. The module according to claim 10, wherein
the interlayer connection section includes a fourth conductor electrically connected to the first conductor via the second conductor, and
the fourth conductor includes an insertion portion surrounded by the inner surface.

12. The module according to claim 11, wherein
an electrical resistance of the fourth conductor is lower than an electrical resistance of the second conductor.

13. The module according to claim 11, wherein
the fourth conductor further includes a support portion connected to the insertion portion and supported by either the first surface or the second surface.

14. The module according to claim 13, wherein
an electrical resistance of the fourth conductor is lower than an electrical resistance of the second conductor.

15. The module according to claim 14, wherein
the inner edge extends in a fourteenth direction crossing the first surface and is connected to the first surface and the second surface, and
a cross-sectional area of the interlayer connection section orthogonal to the fourteenth direction is greater than a cross-sectional area of the first wiring orthogonal to an extension direction of the first wiring.

16. An electronic apparatus having a module comprising:
a substrate including a first surface facing a first direction, a second surface facing a second direction opposite to the first direction, and an inner surface of a hole extending between the first surface and the second surface;
a first wiring provided on the first surface;
a second wiring provided on the second surface; and
an interlayer connection section including a first conductor provided on the inner surface, the first conductor connected to the first wiring and the second wiring, the first conductor being thinner than the first wiring and thinner than the second wiring, and a second conductor disposed in the hole and electrically connected to the first conductor.

17. The apparatus according to claim 16, wherein
the first conductor is configured to feed a current from the first wiring through the second wiring, and
the interlayer connection section includes a first portion extending in a third direction along the first surface and crossing a direction in which the current flows from the first wiring through the first conductor.

18. The apparatus according to claim 16, wherein
the interlayer connection section includes a second portion extending in a fourth direction along the second surface and crossing a direction in which the current flows from the first conductor through the second wiring.

19. The apparatus according to claim 16, wherein
the inner edge extends in a fourteenth direction crossing the first surface and is connected to the first surface and the second surface, and
a cross-sectional area of the interlayer connection section orthogonal to the fourteenth direction is greater than a cross-sectional area of the first wiring orthogonal to an extension direction of the first wiring.

20. A wiring board, comprising:
a substrate including a first surface facing in a first direction, a second surface facing in a second direction opposite to the first direction, and an inner surface of a hole extending between the first surface and the second surface;
a first wiring provided on the first surface;
a second wiring provided on the second surface; and
an interlayer connection section including a first conductor provided on the inner surface, the first conductor connected to the first wiring and the second wiring, the first conductor being thinner than the first wiring and thinner than the second wiring, and a second conductor disposed in the hole and electrically connected to the first conductor.
